(19) United States
(12) Patent Application Publication
(10) Pub. No.: US 2008/0221824 A1
(43) Pub. Date: Sep. 11, 2008

(54) TEST APPARATUS, TEST METHOD AND RECORDING MEDIUM

(75) Inventor: Norio Kumaki, Tokyo (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: ADVANTEST CORPORATION, TOKYO (JP)

(21) Appl. No.: 11/851,395

(22) Filed: Sep. 7, 2007

Related U.S. Application Data
(63) Continuation of application No. PCT/JP2006/304967, filed on Mar. 14, 2006.

(30) Foreign Application Priority Data
Mar. 23, 2005 (JP) JP2005-084576

(51) Int. Cl. G01R 31/02

(52) U.S. Cl. 702/118

(57) ABSTRACT

There is provided a test apparatus for testing a plurality of DUTs. The test apparatus includes a plurality of test modules that are connected to the plurality of DUTs and test the plurality of DUTs, and a CPU that controls test operations performed by the plurality of test modules in accordance with a designated one of operation modes including (i) a parallel test mode in which at least the plurality of test modules are caused to perform a same test simultaneously and in parallel and (ii) an independent test mode in which each of the plurality of test modules is caused to perform a different test independently.

### CROSS REFERENCE TO RELATED APPLICATION

This is a continuation application of PCT/JP2006/304967 filed on Mar. 14, 2006 which claims priority from a Japanese Patent Application(s) NO. 2005-084576 filed on Mar. 23, 2005, the contents of which are incorporated herein by reference.

### BACKGROUND

1. Technical Field

The present invention relates to a test apparatus, a test method, and a recording medium. More particularly, the present invention relates to a test apparatus, a test method, and a recording medium for testing a device under test (DUT) by using a test process executed by a central processing unit (CPU).

2. Related Art

A conventionally-used semiconductor test apparatus includes therein a plurality of test modules for testing a plurality of DUTs. Such a semiconductor test apparatus includes therein a plurality of CPUs which are provided in a one-to-one correspondence with the plurality of test modules. Each of the plurality of test modules is controlled by a corresponding one of the plurality of CPUs. With such a configuration, the test apparatus can test the plurality of DUTs simultaneously and in parallel, thereby improving the testing efficiency.

Since no prior art documents have been found, such documents are not mentioned herein.

A general-purpose CPU which is available at a relatively low cost normally has a mean time between failure (MTBF) of 20 to 30 years. This is a sufficiently long time interval when a single CPU is utilized, or when a small number (approximately five or less) of CPUs are utilized together. However, a single semiconductor test apparatus may test, simultaneously and in parallel, approximately several hundred devices. In this case, even when each test module is capable of testing more than one device, the semiconductor test apparatus requires at least approximately 100 CPUs.

For example, when the semiconductor test apparatus has 100 CPUs provided therein, the MTBF for the entire collection of CPUs is approximately 2,000 hours to 3,000 hours. This time interval is not sufficiently long when considering the failure rates of other constituents of the semiconductor test apparatus. Which is to say, the semiconductor test apparatus having this configuration may have a high failure rate, which may pose a problem in terms of the usefulness of the semiconductor test apparatus. Apart from this issue, an advanced CPU is recently available at a sufficiently low price. Therefore, when one CPU controls one test module, the CPU may still have a surplus processing capability.

### SUMMARY

Therefore, it is an object of an aspect of the present invention to provide a test apparatus, a test method and a recording medium, which are capable of overcoming the above drawbacks accompanying the related art. The above and other objects can be achieved by combinations described in the independent claims. The dependent claims define further advantageous and exemplary combinations of the present invention.

According to a first aspect related to the innovations herein, one exemplary test apparatus may include a test apparatus for testing a plurality of DUTs. The test apparatus includes a plurality of test modules that are connected to the plurality of DUTs and test the plurality of DUTs, and a CPU that controls test operations performed by the plurality of test modules in accordance with a designated one of operation modes including (i) a parallel test mode in which at least the plurality of test modules are caused to perform a same test simultaneously and in parallel and (ii) an independent test mode in which each of the plurality of test modules is caused to perform a different test independently.

According to a second aspect related to the innovations herein, one exemplary test method may include a test method that uses a test apparatus for testing a plurality of DUTs in order to test the plurality of DUTs. Here, the test apparatus includes a plurality of test modules that are connected to the plurality of DUTs and test the plurality of DUTs, and a CPU that controls test operations performed by the plurality of test modules in accordance with a designated operation mode. When the designated operation mode is a parallel test mode in which the plurality of test modules are caused to perform a same test simultaneously and in parallel, the CPU controls the test operations performed by the plurality of test modules by executing a predetermined single test process, and when the designated operation mode is an independent test mode in which each of the plurality of test modules is caused to perform a different test independently, the CPU controls the plurality of test modules in parallel by executing a plurality of test processes in a one-to-one correspondence with the plurality of test modules to control the plurality of test modules in such a manner as to switch from a test process to a different test process among the plurality of test processes.

According to a third aspect related to the innovation herein, one exemplary recording medium may include a recording medium storing thereon a test control program for controlling a test apparatus that tests a plurality of DUTs. Here, the test apparatus includes a plurality of test modules that are connected to the plurality of DUTs and test the plurality of DUTs, and a CPU that controls test operations performed by the plurality of test modules in accordance with a designated operation mode. When the designated operation mode is a parallel test mode in which the plurality of test modules are caused to perform a same test simultaneously and in parallel, the test control program causes the CPU to control the test operations performed by the plurality of test modules by executing a predetermined single test process, and when the designated operation mode is an independent test mode in which each of the plurality of test modules is caused to perform a different test independently, the test control program causes the CPU to control the plurality of test modules in parallel by executing a plurality of test processes in a one-to-one correspondence with the plurality of test modules to control the plurality of test modules in such a manner as to switch from a test process to a different test process among the plurality of test processes.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates the configuration of a test apparatus 10 which is observed when the test apparatus 10 operates in a parallel test mode.

FIG. 2 illustrates the configuration of the test apparatus 10 which is observed when the test apparatus 10 operates in an independent test mode.

FIG. 3 is a timing chart of control phases and test operation phases observed when the test apparatus 10 is in the parallel test mode.

FIGS. 4A and 4B are timing charts of control phases and test operation phases observed when the test apparatus 10 is in the independent test mode.

### DESCRIPTION OF EXEMPLARY EMBODIMENTS

Hereinafter, one aspect of the present invention will be described through an embodiment. The embodiment does not limit the invention according to the claims, and all the combinations of the features described in the embodiment are not necessarily essential to means provided by aspects of the invention.

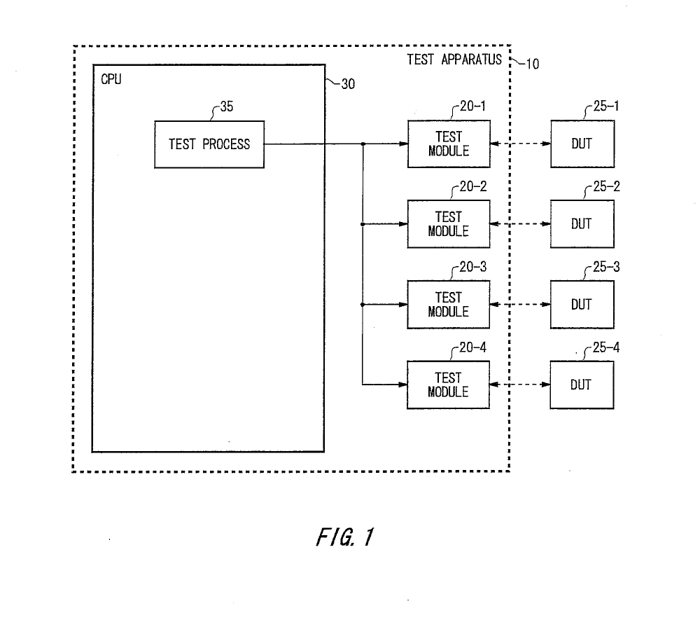

FIG. 1 illustrates the configuration of a test apparatus 10 which is observed when the test apparatus 10 operates in a parallel test mode. The test apparatus 10 includes therein test modules 20-1 to 20-4 and a CPU 30. The test modules 20-1 to 20-4 are connected to devices under test (DUTs) 25-1 to 25-4, and test the DUTs 25-1 to 25-4. For example, each of the test modules 20-1 to 20-4 is connected to a corresponding one of the DUTs 25-1 to 25-4, and tests the corresponding DUT.

The CPU 30 controls the test operations performed by the test modules 20-1 to 20-4 in accordance with a designated operation mode. For example, FIG. 1 illustrates the configuration of the test apparatus 10 which is observed when the designated operation mode is the parallel test mode in which a plurality of test modules are caused to perform the same test simultaneously and in parallel. More specifically, in this case, the CPU 30 executes a test process 35 which is a predetermined test process in order to control the test operations performed by the test modules 20-1 to 20-4. The control of the test operations is described in detail in the following. The test process 35, for example, sends at the same time a parameter necessary for the test operations to the test modules 20-1 to 20-4, so that the parameter is set in the test modules 20-1 to 20-4. The test process 35 may afterwards collect the test results obtained as a result of the test operations performed by the test modules 20-1 to 20-4 and judge whether the DUTs 25-1 to 25-4 pass or fail the test.

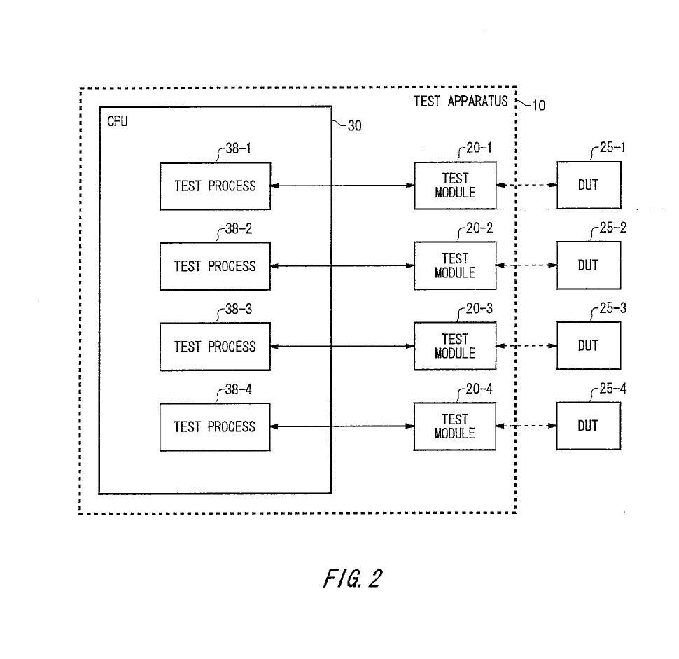

FIG. 2 illustrates the configuration of the test apparatus 10 which is observed when the test apparatus 10 operates in the independent test mode. Similarly to the configuration illustrated in FIG. 1, the test apparatus 10 includes therein the test modules 20-1 to 20-4 and CPU 30. The test modules 20-1 to 20-4 are connected to the DUTs 25-1 to 25-4, and test the DUTs 25-1 to 25-4. The CPU 30 operates in the following manner when the designated operation mode is the independent test mode in which each of a plurality of test modules is caused to independently perform a different test.

The CPU 30 executes a test process for each test module for controlling the test module. In other words, the CPU 30 executes test processes 38-1 to 38-4 in a one-to-one correspondence with the test modules 20-1 to 20-4. The CPU 30 switches from a test process to a different test process among the test processes 38-1 to 38-4 while executing the test processes 38-1 to 38-4, so as to control the test modules 20-1 to 20-4 in parallel. Here, each of the test processes 38-1 to 38-4 independently controls a corresponding one of the test modules 20-1 to 20-4, but the test processes 38-1 to 38-4 may control the test modules 20-1 to 20-4 by using a single shared control line, for example, a PCI bus.

Here, the tests which are respectively controlled by the test processes 38-1 to 38-4 are different from each other, for example, in that DUTs of different types are tested. Alternatively, the tests may be different from each other in that DUTs of the same type are tested in terms of different points. As a further alternative example, the tests are different from each other in that DUTs of the same type are tested in terms of the same point for different time internals.

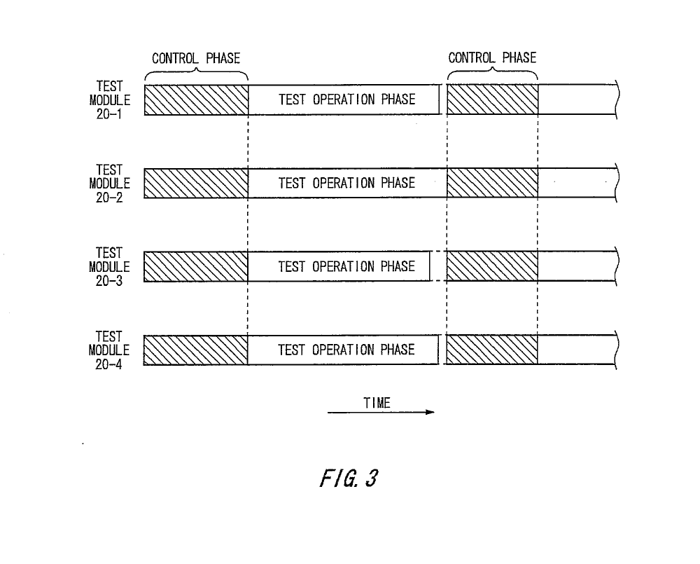

FIG. 3 is a timing chart of control phases and test operation phases observed when the test apparatus 10 is in the parallel test mode. Each of the test modules 20-1 to 20-4 is controlled by the test process 35. For example, each of the test modules 20-1 to 20-4 writes the parameter received from the test process 35 into the register in the test module. This procedure of receiving the parameter and writing the parameter into the register is called “the control phase”. The control phase is performed based on the same parameter received by each of the test modules 20-1 to 20-4 from the test process 35. Therefore, the test modules 20-1 to 20-4 perform the control phases simultaneously and in parallel.

When having been controlled by the test process 35, each of the test modules 20-1 to 20-4 performs a test operation in accordance with the contents of the control. This test operation is called “the test operation phase”. For example, when performing the test operation phase, each of the test modules 20-1 to 20-4 may output a test pattern to a corresponding one of the DUTs 25-1 to 25-4, and collect an output pattern which is output from the corresponding one of the DUTs 25-1 to 25-4 in response to the test pattern.

As shown in FIG. 3, when the test apparatus 10 is in the parallel test mode, only the test process 35 operates on the CPU 30 during the control phases, and the test modules 20-1 to 20-4 are all collectively controlled by the test process 35 during the control phases. For this reason, the control phases are completed within a short time irrespective of the number of the test modules, and the test operation phases are immediately started subsequently. As described above, the test apparatus 10 requires only a short time period for completing the control phases when in the parallel test mode, thereby achieving high efficiency.

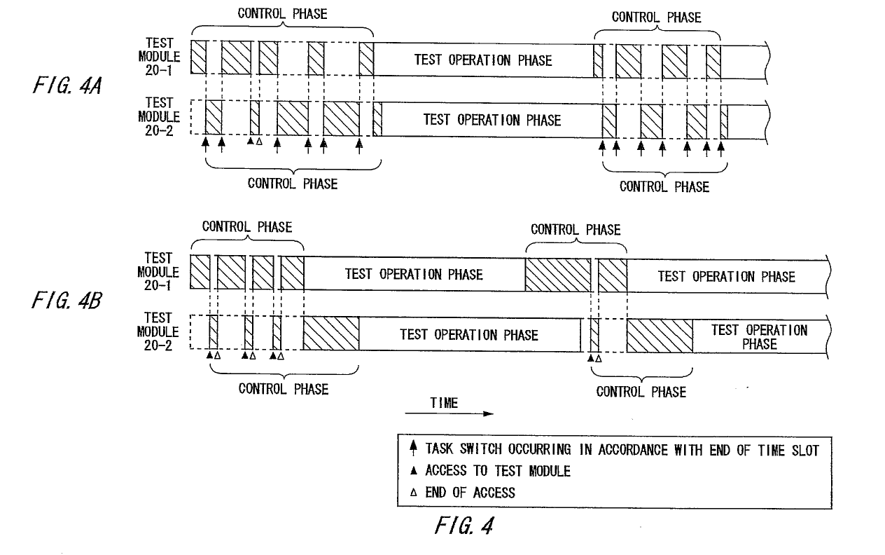

FIG. 4A is a timing chart of the control phases and test operation phases when the test apparatus 10 is in the independent test mode (the first example). In FIG. 4A, only the test modules 20-1 and 20-2 are shown out of the test modules 20-1 to 20-4 for the sake of intelligibility. Here, the test module 20-1 is shown as an example of a first test module relating to the present invention, and the test module 20-2 is shown as an example of a second test module relating to the present invention. At a time shown at the far left of the drawing in FIG. 4A, both of the test modules 20-1 and 20-2 are on standby respectively for the controls to be performed by the corresponding test processes 38-1 and 38-2.

The test module 20-1 is controlled by the test process 38-1, and the test module 20-2 is controlled by the test process 38-2. The CPU 30 executes the test processes 38-1 and 38-2. Strictly speaking, the CPU 30 is incapable of simultaneously executing two or more processes. Therefore, the CPU 30 switches from the test processes 38-1 to the test process 38-2 and vice versa while executing the test processes 38-1 and 38-2 in order to control in parallel the CPUs 30-1 and 30-2. When the processes are switched therebetween based on the function of the operating system (OS), the OS normally assigns a time slot having a predetermined time period to each process.

To be specific, when a predetermined time period has elapsed since the OS starts executing a process, the time slot ends and the OS switches to a different process. Even when the time slot has not ended, the OS switches to a different process if the process enters a standby state for input/output (for example, if the test process accesses a corresponding test module). In a normal case, this procedure is important to equalize the processing speeds among the processes and increase the responsiveness of the processes.

However, the test modules relating to the present embodiment are controlled by the corresponding processes only during the control phases, and, once the control phases end, independently perform test operations without being controlled by the processes. For this reason, the higher efficiency the test apparatus 10 achieves, the smaller the number of test modules which wait for the end of the control phase is. In view of this, the test apparatus 10 relating to the present embodiment preferably performs the tests at the timings described with reference to the following second example.

FIG. 4B is a timing chart of the control phases and test operation phases observed when the test apparatus 10 is in the independent test mode (the second example). Similarly to the example illustrated in FIG. 4A, the test module 20-1 is controlled by the test process 38-1, and the test module 20-2 is controlled by the test process 38-2. The CPU 30 switches from the test process 38-1 to the test process 38-2 and vice versa while executing the test processes 38-1 and 38-2 in order to control in parallel the CPUs 30-1 and 30-2. At a time shown at the far left of the drawing in FIG. 4B, both of the test modules 20-1 and 20-2 are on standby respectively for the controls to be performed by the corresponding test processes 38-1 and 38-2.

According to the example illustrated in FIG. 4B, the CPU 30 gives priority to completing the execution of the test process 38-1 corresponding to the test module 20-1 over completing the execution of the test process 38-2 corresponding to the test module 20-1, differently from the example illustrated in FIG. 4A. When completing the execution of the test process 38-1, the CPU 30 controls the test module 20-2 by executing the test process 38-2 while the test module 20-1 performs the test operation.

However, the efficiency is degraded if the CPU 30 continues executing the prioritized process even when the prioritized process is on standby for input/output. Considering this, the CPU 30 executes the test process 38-2 in place of the test process 38-1 while the test process 38-1 accesses the test module 20-1 and accordingly is on standby. When the test process 38-1 ends its access to the test module 20-1, the CPU 30 restarts executing the test process 38-1 in place of the test process 38-2.

Here, a specific technique to realize prioritized execution of a process and a technique to realize a procedure of switching a process being executed from a process that is on standby for input/output to a different process are conventionally known in the technical field relating to the scheduler of the OS, and thus not explained here.

As described above, the procedure illustrated in FIG. 4B makes it possible to start the test operation phases as soon as possible and to complete the control phases as quickly as possible by making efficient use of the time period during which a process is on standby for input/output.

While one aspect of the present invention has been described through an embodiment, the technical scope of the invention is not limited to the above described embodiment. It is apparent to persons skilled in the art that various alternations and improvements can be added to the above-described embodiment. It is also apparent from the scope of the claims that the embodiments added with such alternations or improvements can be included in the technical scope of the invention.

As is apparent from the above description, an embodiment of the present invention can lower the failure rate of a semiconductor test apparatus by reducing the number of CPUs necessary for controlling the tests.

What is claimed is:

1. A test apparatus for testing a plurality of DUTs, comprising:
a plurality of test modules that are connected to the plurality of DUTs and test the plurality of DUTs; and
a CPU that controls test operations performed by the plurality of test modules in accordance with a designated one of operation modes including (i) a parallel test mode in which at least the plurality of test modules are caused to perform a same test simultaneously and in parallel and (ii) an independent test mode in which each of the plurality of test modules is caused to perform a different test independently.

2. The test apparatus as set forth in claim 1, wherein
when the designated operation mode is the parallel test mode in which the plurality of test modules are caused to perform the same test simultaneously and in parallel, the CPU controls the test operations performed by the plurality of test modules by executing a predetermined single test process, and
when the designated operation mode is the independent test mode in which each of the plurality of test modules is caused to perform a different test independently, the CPU controls the plurality of test modules in parallel by executing a plurality of test processes in a one-to-one correspondence with the plurality of test modules to control the plurality of test modules in such a manner as to switch from a test process to a different test process among the plurality of test processes.

3. The test apparatus as set forth in claim 2, wherein
when controlled by a corresponding test process, each of the plurality of test modules performs a test operation in accordance with contents of the control, and
in a case where the designated operation mode is the independent test mode,
when both of a first test module and a second test module are on standby for controls to be performed by corresponding test processes, the CPU gives priority to completing execution of a first test process corresponding to the first test module over completing execution of a second test process corresponding to the second test module, and controls the second test module while the first test module performs a test operation.

4. The test apparatus as set forth in claim 3, wherein
while the first test process accesses the first test module and is on standby, the CPU executes the second test process in place of the first test process.

5. The test apparatus as set forth in claim 4, wherein
when the first test process ends the access to the first test module, the CPU restarts executing the first test process in place of the execution of the second test process.

6. A test method that uses a test apparatus for testing a plurality of DUTs in order to test the plurality of DUTs,
the test apparatus including:
a plurality of test modules that are connected to the plurality of DUTs and test the plurality of DUTs; and
a CPU that controls test operations performed by the plurality of test modules in accordance with a designated operation mode, wherein
when the designated operation mode is a parallel test mode in which the plurality of test modules are caused to perform a same test simultaneously and in parallel, the CPU controls the test operations performed by the plurality of test modules by executing a predetermined single test process, and
when the designated operation mode is an independent test mode in which each of the plurality of test modules is caused to perform a different test independently, the CPU controls the plurality of test modules in parallel by executing a plurality of test processes in a one-to-one correspondence with the plurality of test modules to control the plurality of test modules in such a manner as to switch from a test process to a different test process among the plurality of test processes.

7. A recording medium storing thereon a test control program for controlling a test apparatus that tests a plurality of DUTs,
the test apparatus including:
a plurality of test modules that are connected to the plurality of DUTs and test the plurality of DUTs; and
a CPU that controls test operations performed by the plurality of test modules in accordance with a designated operation mode, wherein
when the designated operation mode is a parallel test mode in which the plurality of test modules are caused to perform a same test simultaneously and in parallel, the test control program causes the CPU to control the test operations performed by the plurality of test modules by executing a predetermined single test process, and
when the designated operation mode is an independent test mode in which each of the plurality of test modules is caused to perform a different test independently, the test control program causes the CPU to control the plurality of test modules in parallel by executing a plurality of test processes in a one-to-one correspondence with the plurality of test modules to control the plurality of test modules in such a manner as to switch from a test process to a different test process among the plurality of test processes.
